(19) United States
(12) Patent Application Publication
(10) Pub. No.: US 2006/0163682 A1
(43) Pub. Date: Jul. 27, 2006

(54) Semiconducting photo detector structure

(76) Inventors: Shyi-Ming Pan, Chang-Hua City (TW); Fen-Ren Chien, Yonghe City (TW)

Correspondence Address: LIN & ASSOCIATES INTELLECTUAL PROPERTY, P.O. BOX 2339, SARATOGA, CA, 95070-0339, US

(21) Appl. No.: 11/041,492

(22) Filed: Jan. 22, 2005

(51) Int. Cl. H01L 27/14

(52) U.S. Cl. 257/431

(57) ABSTRACT

An epitaxial structure for semiconducting photo detectors is provided. The epitaxial structure contains a substrate having a built-in electric circuit, a first and second metallic layers on top of said substrate electrically connected to the corresponding electrical input and output points of the substrate's electric circuit, and a semiconducting photo detecting element as the topmost part for receiving incident lights.

### BACKGROUND OF THE INVENTION

1. Field of the Invention

The present invention generally relates to semiconducting photo detectors and, more particularly, to an epitaxial structure of semiconducting photo detectors.

2. The Prior Arts

Conventional semiconducting photo detectors are formed by growing an epitaxial structure on a substrate. FIG. 3 is a schematic diagram showing the epitaxial structure of semiconducting photo detectors according to prior arts. As shown in FIG. 3, a semiconducting photo detector 402 is formed by a p-type layer 402b and an n-type layer 402a, sequentially stacked in this order from bottom to top on a substrate 401. The p-type layer 402b is made of a p-type material such as a p-type gallium-nitride (GaN) based material. The n-type layer 402a is made of an n-type material such as an n-type GaN-based material. Also on top of a part of the p-type layer's top surface, there is a positive electrode layer 402d having an ohmic contact with the p-type layer 402b. On the other hand, there is a negative electrode layer 402c on top of the n-type layer and has an ohmic contact with the n-type layer 402a. The positive and negative electrode layers 402d and 402c are the contacting points for electrical input and output of the semiconducting photo detector 402. By the photoelectrical effect of the p-type and n-type layers 402b and 402a, the lights entering from the top of the semiconducting photo detector 402 are converted into electrical signals so as to achieve the goal of detecting lights. However, a significant portion of the incident lights would be absorbed by the materials used for the positive and negative electrode layers 402d and 402c, and thereby causes an inefficient photoelectric conversion and the responsiveness to lights in the semiconducting photo detector 402.

Accordingly, the present invention is aimed at solving the problems associated with conventional semiconducting photo detectors.

### SUMMARY OF THE INVENTION

The present invention provides an epitaxial structure for the semiconducting photo detectors so that the limitations and disadvantages from the prior arts can be obviated practically.

An objective of the present invention is to use a flip chip packaging for the semiconducting photo detectors so that the incident lights would not be obstructed by the electrode layers, the light reception surface area is greatly increased, and therefore photoelectric conversion efficiency is significantly increased for the semiconducting photo detectors.

Another objective of the present invention is to use a metallic layer for a full surface attachment by a flip chip bonder between the semiconducting photo detector and its substrate so that the strength of the attachment could be increased, the production cost could be further reduced, and the production yield is significantly enhanced, compared to the conventional means of using gold bumps to form a partial attachment.

To achieve the foregoing objectives, the present invention provides a semiconducting photo detector structure comprising: a substrate having a built-in electric circuit; at least a first and a second metallic layers on top of the substrate and both are electrically connected to the corresponding electrical input and output points of the substrate's electric circuit; and a semiconducting photo detecting element attached to the top of the first and second metallic layers. The incident lights enter the semiconducting photo detector from the top of semiconducting photo detecting element.

The foregoing and other objects, features, aspects and advantages of the present invention will become better understood from a careful reading of a detailed description provided herein below with appropriate reference to the accompanying drawings.

### BRIEF DESCRIPTION OF THE DRAWINGS

FIG. 1 is a schematic diagram showing the epitaxial structure of semiconducting photo detectors according to an embodiment of the present invention.

FIG. 2 is a schematic diagram showing the epitaxial structure of semiconducting photo detectors according to another embodiment of the present invention.

FIG. 3 is a schematic diagram showing the epitaxial structure of semiconducting photo detectors according to prior arts.

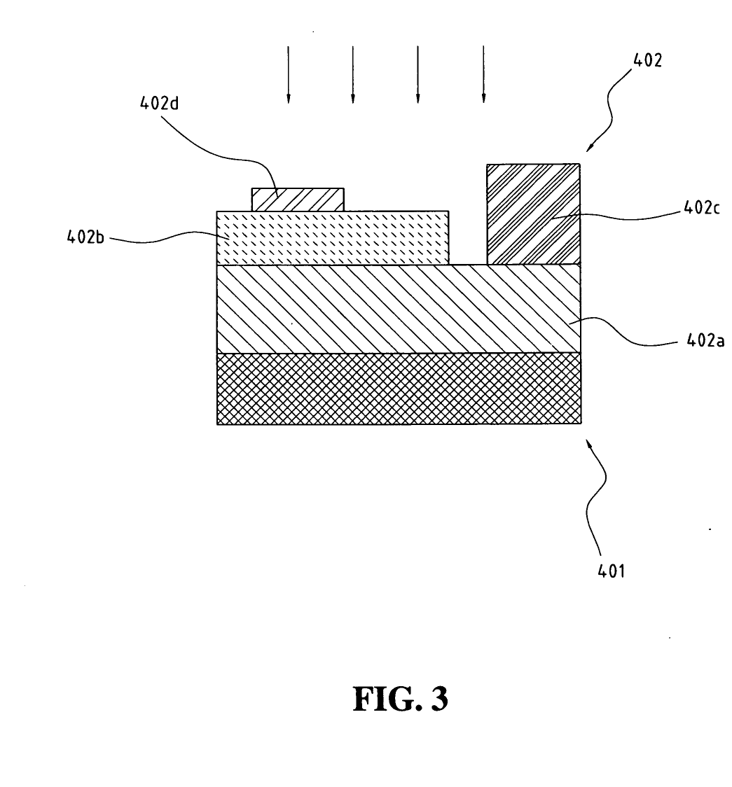

### DETAILED DESCRIPTION OF THE PREFERRED EMBODIMENTS

In the following, detailed description along with the accompanied drawings is given to better explain preferred embodiments of the present invention. Please be noted that, in the accompanied drawings, some parts are not drawn to scale or are somewhat exaggerated, so that people skilled in the art can better understand the principles of the present invention.

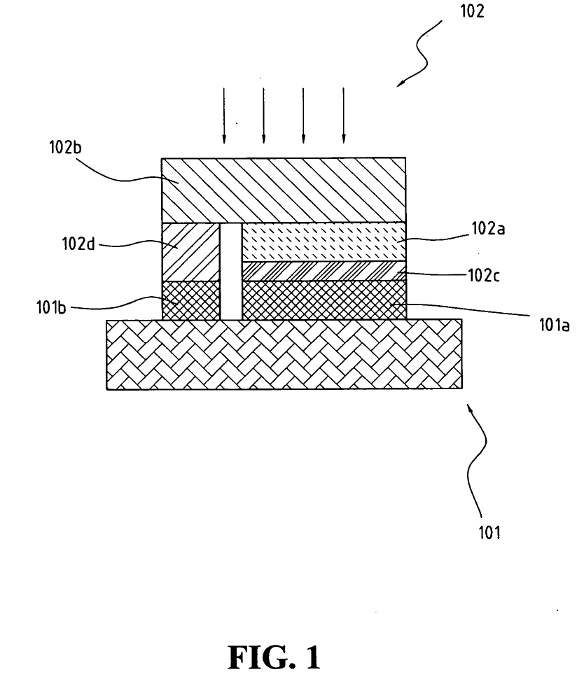

FIG. 1 is a schematic diagram showing the epitaxial structure of semiconducting photo detectors according to an embodiment of the present invention.

As shown in FIG. 1, the epitaxial structure mainly comprises a substrate 101 and a photo detecting element 102 on top of the substrate 101. The photo detecting element is formed using a flip chip process and receives incident lights from its top.

The substrate 101 has a built-in electric circuit. On top of the substrate 101, there is a first metallic layer 101a and a second metallic layer 101b. The first and second metallic layers 101a and 101b are electrically connected to the corresponding electrical input and output points of the substrate 101's electric circuit, so that electrical signals can be transmitted between the photo detecting element 102 and the substrate 101.

The substrate 101 may contain a lead frame. The electrical signals are then exchanged with the outside world through the substrate 101's lead frame.

The photo detecting element 102 is a semiconductor device made of, for example, a GaN-based material. The photo detecting element 102 comprises a p-type layer 102a and an n-type layer 102b stacked on top of the p-type layer 102a. The p-type layer 102a is made of a p-type material such as a p-type GaN-based material. On the other hand, the n-type layer 102b is made of an n-type material such as an n-type GaN-based material. The photo detecting element 102 further comprises a positive electrode layer 102c located beneath the p-type layer 102a. The positive electrode layer 102c forms an ohmic contact with the p-type layer 102a. In addition, the photo detecting element 102 comprises a negative electrode layer 102d located beneath the n-type layer 102b. The negative electrode layer 102d also forms an ohmic contact with the n-type layer 102b.

According to the present embodiment, the n-type layer 102b is exposed completely as a topmost part of the photo detecting element 102 and there is no obstruction for the incident lights to enter the photo detecting element 102.

The first and second metallic layers 101a and 101b correspond to the p-type electrode layer 102c and the n-type electrode layer 102d respectively, in terms of their positions and the area of their contact surfaces. The first and second metallic layers 101a and 101b adhere to the p-type electrode layer 102c and the n-type electrode layer 102d respectively, so that the photo detecting element 102 is attached to the substrate 101 and an electrical connection is established therebetween.

For semiconducting photo detectors based on the present embodiment, incident lights enter into the photo detecting element 102 through the topmost n-type layer 102b, pass through the junction between the n-type and p-type layers 102b and 102a, and reach the p-type layer 102a. Along the way, the lights excite the electrons of the semiconducting materials and cause free electrons and holes to appear. Therefore, when the junction between the n-type and p-type layers 102b and 102a is properly biased, an electrical current would be generated and the incident light signals are thereby detected.

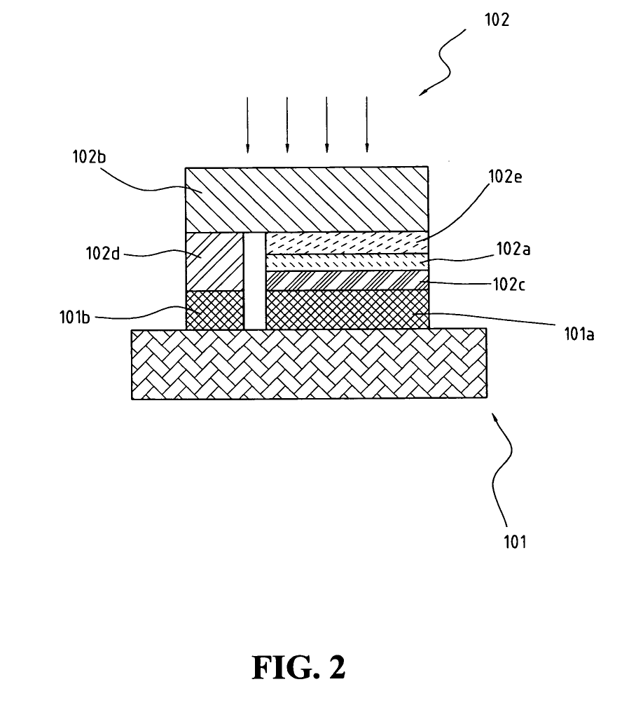

FIG. 2 is a schematic diagram showing the epitaxial structure of semiconducting photo detectors according to another embodiment of the present invention.

As shown in FIG. 2, the present embodiment has an epitaxial structure almost identical to that of the previous embodiment, except that a neutral layer 102e is interposed between the p-type layer 102a and the n-type layer 102b. The neutral layer 102e is made of an intrinsic semiconducting material such as undoped GaN-based material and, therefore, a PIN junction is formed within the semiconducting photo detector according to the present embodiment.

Although the present invention has been described with reference to the preferred embodiments, it will be understood that the invention is not limited to the details described thereof. Various substitutions and modifications have been suggested in the foregoing description, and others will occur to those of ordinary skill in the art. Therefore, all such substitutions and modifications are intended to be embraced within the scope of the invention as defined in the appended claims.

What is claimed is:

1. A semiconducting photo detector structure, comprising:
a substrate having a built-in electric circuit with a plurality of electrical signal input and output points;
a first metallic layer located on top of said substrate and electrically connected to a corresponding set of said electrical signal input and output points;
a second metallic layer located on top of said substrate but not overlapping with said first metallic layer electrically connected to a corresponding set of said electrical signal input and output points;
a positive electrode layer located on top of said first metallic layer;
a negative electrode layer located on top of said second metallic layer; and
a semiconducting photo detecting element through which incident lights enter into said semiconducting photo detector, located on top of said positive and negative electrode layers,
wherein said first and second metallic layers electrically connect to said positive and negative electrode layers respectively.

2. The semiconducting photo detector structure as claimed in claim 1, wherein top surfaces of said first and second metallic layers have areas different from those of corresponding bottom surfaces of said positive and negative electrode layers.

3. The semiconducting photo detector structure as claimed in claim 1, wherein top surfaces of said first and second metallic layers have areas identical to those of corresponding bottom surfaces of said positive and negative electrode layers.

4. The semiconducting photo detector structure as claimed in claim 1, wherein said semiconducting photo detecting element electrically connects to said substrate via said first and second metallic layers and said positive and negative electrode layers.

5. The semiconducting photo detector structure as claimed in claim 1, wherein said semiconducting photo detecting element further comprises a p-type layer made of p-type semiconducting material forming an ohmic contact with said positive electrode layer, and an n-type layer located on top of said p-type layer made of n-type semiconducting material forming an ohmic contact with said negative electrode layer.

6. The semiconducting photo detector structure as claimed in claim 5, wherein said n-type layer is exposed as a topmost part of said semiconducting photo detector.

7. The semiconducting photo detector structure as claimed in claim 5, wherein said p-type material is a p-type GaN-based material and said n-type material is an n-type GaN-based material.

8. The semiconducting photo detector structure as claimed in claim 1, wherein said substrate further comprises a lead frame electrically connected to said photo detecting element for exchanging electrical signal with devices outside said semiconducting photo detector.

9. The semiconducting photo detector structure as claimed in claim 1 further comprising a neutral layer made of an intrinsic semiconducting material interposed between said p-type and n-type layers.

10. The semiconducting photo detector structure as claimed in claim 9, wherein said intrinsic semiconducting material is an undoped GaN-based material.
